(19) United States
(12) Patent Application Publication
(10) Pub. No.: US 2024/0234603 A9
(43) Pub. Date: Jul. 11, 2024

(54) SOLAR WINDOW SYSTEM

(71) Applicant: Marcus L. Troy, White oak, NC (US)

(72) Inventor: Marcus L. Troy, White oak, NC (US)

(21) Appl. No.: 18/490,556

(22) Filed: Oct. 19, 2023

Related U.S. Application Data
(60) Provisional application No. 63/380,323, filed on Oct. 20, 2022.

(51) Int. Cl. H01L 31/048; H02S 30/10; H02S 40/32

(52) U.S. Cl. CPC H01L 31/0488; H02S 30/10; H02S 40/32

(57) ABSTRACT

A solar window system includes a window frame, a plurality of photovoltaic cells, and an inverter for converting direct current electric energy generated by the plurality of photovoltaic cells into alternating current electric energy. The plurality of photovoltaic cells is disposed on an outer surface of the window frame. The inverter being electrically connected to the plurality of photovoltaic cells.

### FIELD OF THE INVENTION

The present invention relates generally to a photovoltaic window. More specifically, the present invention is a photovoltaic window system solar photovoltaic power generation. The present invention is specifically designed for windows of residential or commercial properties. However, the present invention is not limited to this option, and it may further be adapted for different purposes.

### BACKGROUND OF THE INVENTION

Windows, and particularly glass windows, provide a degree of functionality as well as aesthetics. Windows may comprise a relatively large surface area in today's buildings and homes, particularly in modern high-rise buildings where entire exterior façades are covered with windows. Windows allow for passive use of solar energy by permitting light and heat from the sun pass into an interior space for illumination and warmth. However, there remains a desire to actively harness solar energy and, in particular, by using the surface area available in windows to capture this energy.

### SUMMARY OF THE INVENTION

The present invention discloses a solar window system that comprises a window frame, a plurality of photovoltaic cells, and an inverter for converting direct current electric energy generated by the plurality of photovoltaic cells into alternating current electric energy. The plurality of photovoltaic cells is disposed on an outer surface of the window frame. The inverter is electrically connected to the plurality of photovoltaic cells.

### BRIEF DESCRIPTION OF THE DRAWINGS

The accompanying drawings, which are included to provide a further understanding of the invention are incorporated in and constitute a part of this specification, illustrate an embodiment of the invention and together with the description serve to explain the principles of the invention. They are meant to be exemplary illustrations provided to enable persons skilled in the art to practice the disclosure and are not intended to limit the scope of the present invention. That is, the dimensions of the components of the present invention, independently and in relation to each other can be different. It should be noted that the drawings are schematic and not necessarily drawn to scale. Some drawings are enlarged or reduced to improve drawing legibility.

FIG. 1 depicts the photovoltaic cells mounted on the window frame of the present invention.

FIG. 2 depicts the photovoltaic cells mounted on the shutters of the present invention.

FIG. 3 depicts the first embodiment of the present invention.

FIG. 4 depicts the first embodiment of the present invention, wherein the enclosure is mounted beneath the windowsill.

FIG. 5 depicts the second embodiment of the present invention.

FIG. 6 depicts the second embodiment of the present invention, wherein the enclosure is mounted beneath the windowsill.

### DETAIL DESCRIPTIONS OF THE INVENTION

As a preliminary matter, it will readily be understood by one having ordinary skill in the relevant art that the present disclosure has broad utility and application. As should be understood, any embodiment may incorporate only one or a plurality of the above-disclosed aspects of the disclosure and may further incorporate only one or a plurality of the above-disclosed features. Furthermore, any embodiment discussed and identified as being “preferred” is considered to be part of a best mode contemplated for carrying out the embodiments of the present disclosure. Other embodiments also may be discussed for additional illustrative purposes in providing a full and enabling disclosure. Moreover, many embodiments, such as adaptations, variations, modifications, and equivalent arrangements, will be implicitly disclosed by the embodiments described herein and fall within the scope of the present disclosure.

Accordingly, while embodiments are described herein in detail in relation to one or more embodiments, it is to be understood that this disclosure is illustrative and exemplary of the present disclosure and is made merely for the purposes of providing a full and enabling disclosure. The detailed disclosure herein of one or more embodiments is not intended, nor is to be construed, to limit the scope of patent protection afforded in any claim of a patent issuing here from, which scope is to be defined by the claims and the equivalents thereof. It is not intended that the scope of patent protection be defined by reading into any claim a limitation found herein that does not explicitly appear in the claim itself. Accordingly, it is intended that the scope of patent protection is to be defined by the issued claim(s) rather than the description set forth herein.

Additionally, it is important to note that each term used herein refers to that which an ordinary artisan would understand such term to mean based on the contextual use of such term herein. When not explicitly defined herein, to the extent that the meaning of a term used herein—as understood by the ordinary artisan based on the contextual use of such term—differs in any way from any particular dictionary definition of such term, it is intended that the meaning of the term as understood by the ordinary artisan should prevail.

Furthermore, it is important to note that, as used herein, “a” and “an” each generally denotes “at least one,” but does not exclude a plurality unless the contextual use dictates otherwise. When used herein to join a list of items, “or” denotes “at least one of the items,” but does not exclude a plurality of items of the list. Finally, when used herein to join a list of items, “and” denotes “all of the items of the list.”

The following detailed description refers to the accompanying drawings. Wherever possible, the same reference numbers are used in the drawings and the following description to refer to the same or similar elements. While many embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims. The present disclosure contains headers. It should be understood that these headers are used as references and are not to be construed as limiting upon the subject matter disclosed under the header.

Other technical advantages may become readily apparent to one of ordinary skill in the art after review of the following figures and description. It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below.

Unless otherwise indicated, the drawings are intended to be read together with the specification and are to be considered a portion of the entire written description of this invention. As used in the following description, the terms “horizontal”, “vertical”, “left”, “right”, “up”, “down” and the like, as well as adjectival and adverbial derivatives thereof (e.g., “horizontally”, “rightwardly”, “upwardly”, “radially”, etc.), simply refer to the orientation of the illustrated structure as the particular drawing figure faces the reader. Similarly, the terms “inwardly,” “outwardly” and “radially” generally refer to the orientation of a surface relative to its axis of elongation, or axis of rotation, as appropriate. As used herein, the term “proximate” refers to positions that are situated close/near in relationship to a structure. As used in the following description, the term “distal” refers to positions that are situated away from positions.

The present disclosure includes many aspects and features. Moreover, while many aspects and features relate to, and are described in the context of solar window system, embodiments of the present disclosure are not limited to use only in this context.

The present invention is a solar window system that is designed to harvest solar energy. It is an aim of the present invention to provide a solar window system that allows a room to function as a standalone unit. It is another aim of the present invention to provide a solar window system that is simple in structure, inexpensive to manufacture, and easy to use. The present invention could be used in traditional homes or prefabricated homes including but not limited to manufactured, modular and mobile homes.

Referring now to the figures of the present disclosure. The solar window system of the present invention comprises a window frame 110, a plurality of photovoltaic cells 120, and an inverter 240.

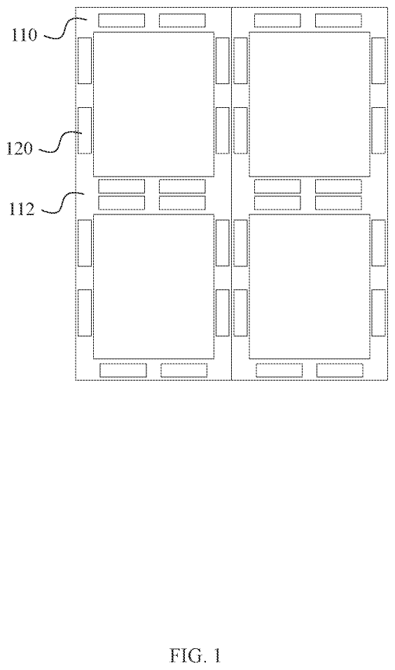

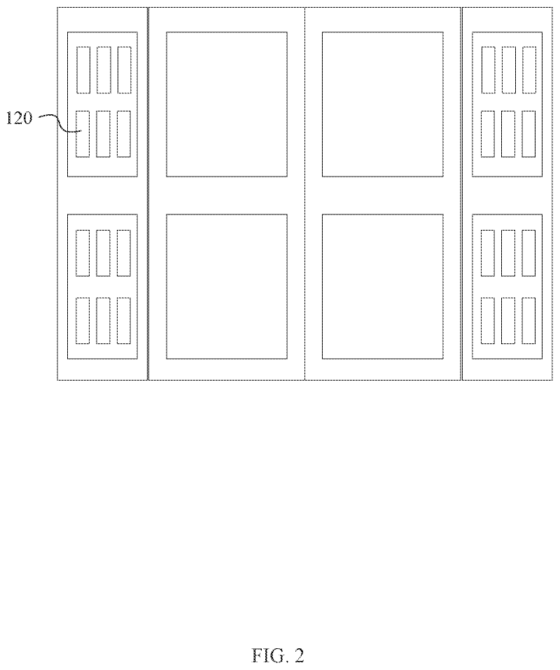

The plurality of photovoltaic cells 120 is disposed on an outer surface 112 of the window frame 110, as shown in FIG. 1. It should be noted that the plurality of photovoltaic cells 120 can be of any shape, size, material, features, type or kind, orientation, location, quantity, components, and arrangements of components that would allow the present invention to fulfill the objectives and intents of the present invention. A photovoltaic cell is understood as an electrical device that converts the energy of light into electricity by the photovoltaic effect, wherein voltage or an electric current is created in a material upon exposure to light. In one embodiment, the width of the plurality of photovoltaic cells 120 is slightly smaller than the width of the window frame 110 so as to maximize the utilization of solar energy. The plurality of photovoltaic cells 120 may be single-junction photovoltaic cells or multijunction photovoltaic cells. In one embodiment, the plurality of photovoltaic cells 120 may be copper indium gallium selenide (“CIGS”) cells. In one embodiment, the plurality of photovoltaic cells 120 may be disposed on shutters, as shown in FIG. 2.

The inverter 240 is configured for converting direct current electric energy generated by the plurality of photovoltaic cells 120 into alternating current electric energy. It should be noted that the inverter 240 can be of any shape, size, material, features, type or kind, orientation, location, quantity, components, and arrangements of components that would allow the present invention to fulfill the objectives and intents of the present invention. The inverter 240 is electrically connected to the plurality of photovoltaic cells 120. In one embodiment, the inverter 240 may be a microinverter.

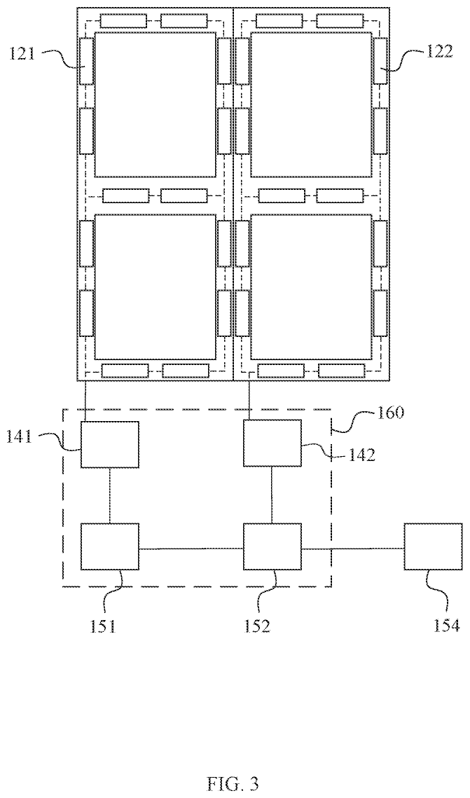

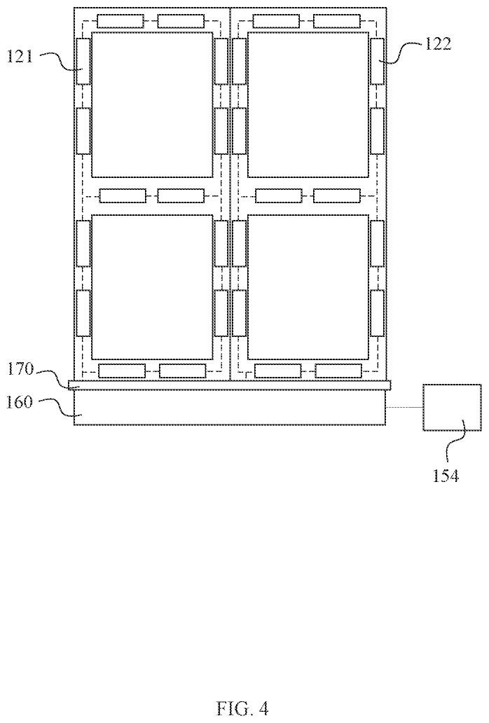

In a first embodiment of the present invention, as illustrated in FIGS. 3-4, the solar window system of the present invention further comprises a first AC (“Alternating Current”) distributor 151 and a second AC distributor 152. In this embodiment, the plurality of photovoltaic cells 120 comprises a first plurality of photovoltaic cells 121 and a second plurality of photovoltaic cells 122. Moreover, the inverter comprises a first inverter 141 and a second inverter 142. The first inverter 141 is associated with the first plurality of photovoltaic cells 121, while the second inverter 142 is associated with the second plurality of photovoltaic cells 122. Specifically, the first inverter 141 is electrically connected between the first plurality of photovoltaic cells 121 and the first AC distributor 151, and the second inverter 142 is electrically connected between the second plurality of photovoltaic cells 122 and second AC distributor 152. Furthermore, the first AC distributor 151 is electrically connected in series with the second AC distributor 152. An electric device 154 may be electrically connected to second AC distributor 152 such that the first plurality of photovoltaic cells 121 and second plurality of photovoltaic cells 122 collectively supply power to the electric device 154. In a preferred embodiment, the first AC distributor 151 and the second AC distributor 152 are microinverters.

In one embodiment, the solar window system further comprises an enclosure 160. The enclosure 160 is configured to enclose the first AC distributor 151, the second AC distributor 152, the first inverter 141, and the second inverter 142. Preferably, the enclosure 160 is mounted beneath a windowsill 170.

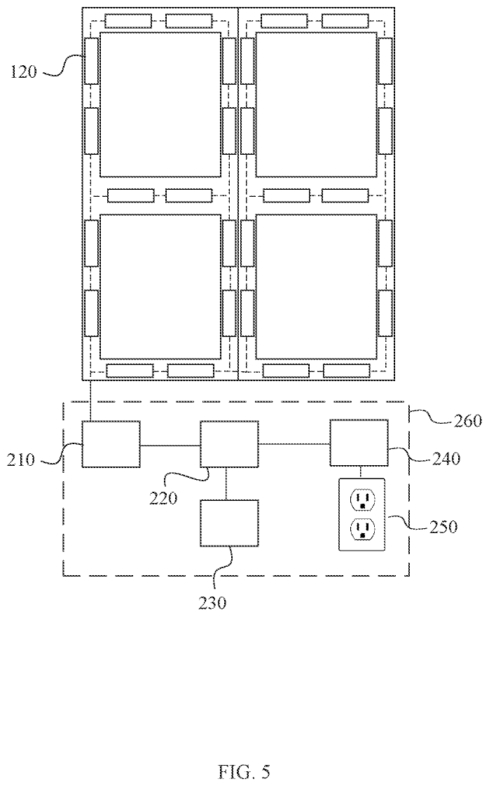

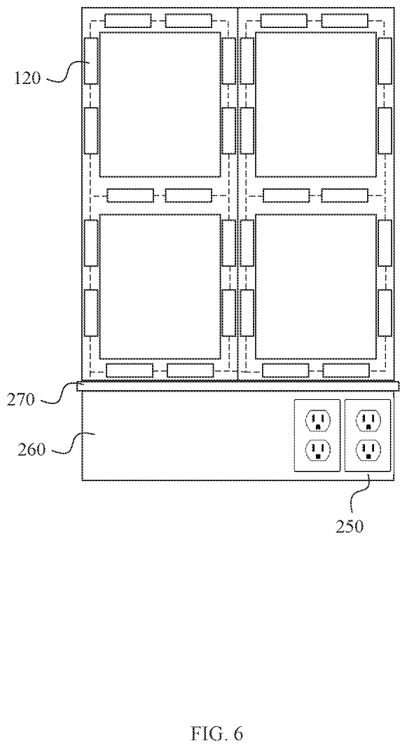

In a second embodiment of the present invention, as illustrated in FIGS. 5-6, the solar window system comprises a circuit breaker 210, a charge controller 220, and a rechargeable battery 230. The circuit breaker 210 is electrically connected between the charge controller 220 and the plurality of photovoltaic cells 120. The circuit breaker 210 is configured to selectively connect or disconnect the plurality of photovoltaic cells 120 from the charge controller 220. In a preferred embodiment, the circuit breaker 210 is a miniature circuit breaker. The rechargeable battery 230 is electrically connected to the charge controller 220 such that the rechargeable battery 230 could be charged under the control of the charge controller 220. The charge controller 220 is configured to charge the rechargeable battery 230. Moreover, the charge controller 220 is further configured to allow the rechargeable battery 230 to supply power to an external load. In one embodiment, the solar window system further comprises an electrical outlet 250. The inverter 240 is electrically connected between the charge controller 220 and the electrical outlet 250. In a preferred embodiment, the solar window system further comprises an enclosure 260 to enclose the circuit breaker 210, the charge controller 220, the rechargeable battery 230, and the inverter 240. Moreover, the electrical outlet 250 is disposed on the enclosure 160. Preferably, the enclosure 260 is mounted beneath a windowsill 270.

Although the disclosure has been explained in relation to its preferred embodiment, it is to be understood that many other possible modifications and variations can be made without departing from the spirit and scope of the disclosure.

What is claimed is:

1. A solar window system, comprising:
a window frame;
a plurality of photovoltaic cells;
an inverter for converting direct current electric energy generated by the plurality of photovoltaic cells into alternating current electric energy;
the plurality of photovoltaic cells being disposed on an outer surface of the window frame; and
the inverter being electrically connected to the plurality of photovoltaic cells.

2. The solar window system as claimed in claim 1, further comprising:
a first AC distributor;
a second AC distributor;
the plurality of photovoltaic cells comprising a first plurality of photovoltaic cells and a second plurality of photovoltaic cells;
the inverter comprising a first inverter and a second inverter;
the first inverter being electrically connected between the first plurality of photovoltaic cells and the first AC distributor;
the second inverter being electrically connected between the second plurality of photovoltaic cells and second AC distributor; and
the first AC distributor being electrically connected in series with the second AC distributor.

3. The solar window system as claimed in claim 2, wherein an electric device is electrically connected to second AC distributor.

4. The solar window system as claimed in claim 2, further comprising:
an enclosure;
the first AC distributor, the second AC distributor, the first inverter, and the second inverter being enclosed in the enclosure.

5. The solar window system as claimed in claim 4, wherein the enclosure is mounted beneath a windowsill.

6. The solar window system as claimed in claim 2, wherein the first AC distributor and the second AC distributor are microinverters.

7. The solar window system as claimed in claim 1, further comprising:
a circuit breaker;
a charge controller;
a rechargeable battery;
the circuit breaker being electrically connected between the charge controller and the plurality of photovoltaic cells;
the rechargeable battery being electrically connected to the charge controller;
the charge controller being configured to charge the rechargeable battery.

8. The solar window system as claimed in claim 7, further comprising:
an electrical outlet;
the inverter being electrically connected between the charge controller and the electrical outlet.

9. The solar window system as claimed in claim 8, further comprising:
an enclosure;
the circuit breaker, the charge controller, the rechargeable battery, and the inverter being enclosed in the enclosure; and
the electrical outlet being disposed on the enclosure.

10. The solar window system as claimed in claim 9, wherein the enclosure is mounted beneath a windowsill.

11. The solar window system as claimed in claim 7, wherein the inverter is a microinverter.

12. The solar window system as claimed in claim 7, wherein the circuit breaker is a miniature circuit breaker.
